(19) United States
(12) Patent Application Publication
(10) Pub. No.: US 2026/0068047 A1
(43) Pub. Date: Mar. 5, 2026

(54) WIRING SUBSTRATE AND METHOD FOR MANUFACTURING WIRING SUBSTRATE

(71) Applicant: IBIDEN CO., LTD., Gifu (JP)

(72) Inventors: Yuma ITO, Gifu (JP); Shunya HATANAKA, Gifu (JP)

(73) Assignee: IBIDEN CO., LTD., Gifu (JP)

(21) Appl. No.: 19/317,363

(22) Filed: Sep. 3, 2025

(30) Foreign Application Priority Data
Sep. 4, 2024 (JP) 2024-152497

(51) Int. Cl. H05K 1/11; H05K 3/42

(52) U.S. Cl. CPC H05K 1/115; H05K 3/42; H05K 2201/09827; H05K 2203/107

(57) ABSTRACT

A wiring substrate includes a conductor layer, an insulating layer formed on the conductor layer such that the insulating layer is covering the conductor layer, and a via conductor formed in a through hole penetrating through the insulating layer such that the through hole has a first opening on the opposite side with respect to the conductor layer and a second opening facing the conductor layer and that the via conductor is connecting to the conductor layer. The conductor layer has a surface facing the via conductor and having a recess communicating with the through hole such that the recess is smaller than the second opening and has a conical shape tapering toward the opposite side with respect to the via conductor and the recess has the center on the surface of the conductor layer that is offset from the center of the first opening of the through hole.

### CROSS-REFERENCE TO RELATED APPLICATIONS

The present application is based upon and claims the benefit of priority to Japanese Patent Application No. 2024-152497, filed Sep. 4, 2024, the entire contents of which are incorporated herein by reference.

### BACKGROUND OF THE INVENTION

### Field of the Invention

The present invention relates to a wiring substrate and a method for manufacturing the wiring substrate.

### Description of Background Art

International Publication No. 2020/241645 describes a multilayer wiring substrate. The entire contents of this publication are incorporated herein by reference.

### SUMMARY OF THE INVENTION

According to one aspect of the present invention, a wiring substrate includes a conductor layer, an insulating layer formed on the conductor layer such that the insulating layer is covering the conductor layer, and a via conductor formed in a through hole penetrating through the insulating layer such that the through hole has a first opening on the opposite side with respect to the conductor layer and a second opening facing the conductor layer and that the via conductor is connecting to the conductor layer. The conductor layer has a surface facing the via conductor and having a recess communicating with the through hole such that the recess is smaller than the second opening and has a conical shape tapering toward the opposite side with respect to the via conductor and the recess has the center on the surface of the conductor layer that is offset from the center of the first opening of the through hole.

According to another aspect of the present invention, a method for manufacturing a wiring substrate includes forming a conductor layer, forming an insulating layer on a conductor layer such that the insulating layer covers the conductor layer, forming a through hole in the insulating layer such that the through hole has a first opening facing away from the conductor layer and a second opening facing the conductor layer, and forming a via conductor in the rough hole of the insulating layer such that the via conductor is connected to the conductor layer in the through hole. The forming of the through hole includes forming, on a surface of the conductor layer on an insulating layer side, a recess having a conical shape that tapers toward the opposite side with respect to the through hole such that the center of the recess is offset from the center of the first opening of the through hole.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is an enlarged view of a portion (II) of the wiring substrate of FIG. 1;

FIG. 3A is a plan view schematically illustrating a through hole and a recess in the wiring substrate of FIG. 1;

FIG. 3B schematically illustrates a cross section of a through hole and a recess in the wiring substrate of FIG. 1;

FIG. 4A is a cross-sectional view illustrating an example of a wiring substrate being manufactured using a method for manufacturing a wiring substrate according to an embodiment of the present invention;

FIG. 4B is a cross-sectional view illustrating an example of a wiring substrate being manufactured using a method for manufacturing a wiring substrate according to an embodiment of the present invention;

FIG. 4C is a cross-sectional view illustrating an example of a wiring substrate being manufactured using a method for manufacturing a wiring substrate according to an embodiment of the present invention;

FIG. 4D is a cross-sectional view illustrating an example of a wiring substrate being manufactured using a method for manufacturing a wiring substrate according to an embodiment of the present invention;

FIG. 4E is a cross-sectional view illustrating an example of a wiring substrate being manufactured using a method for manufacturing a wiring substrate according to an embodiment of the present invention;

FIG. 4F is a cross-sectional view illustrating an example of a wiring substrate being manufactured using a method for manufacturing a wiring substrate according to an embodiment of the present invention;

FIG. 4G is a cross-sectional view illustrating an example of a wiring substrate being manufactured using a method for manufacturing a wiring substrate according to an embodiment of the present invention;

FIG. 4H is a cross-sectional view illustrating an example of a wiring substrate being manufactured using a method for manufacturing a wiring substrate according to an embodiment of the present invention;

FIG. 4I is a cross-sectional view illustrating an example of a wiring substrate being manufactured using a method for manufacturing a wiring substrate according to an embodiment of the present invention;

FIG. 4J is a cross-sectional view illustrating an example of a wiring substrate being manufactured using a method for manufacturing a wiring substrate according to an embodiment of the present invention; and

FIG. 4K is a cross-sectional view illustrating an example of a wiring substrate in a completed state manufactured using a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Structure of Wiring Substrate

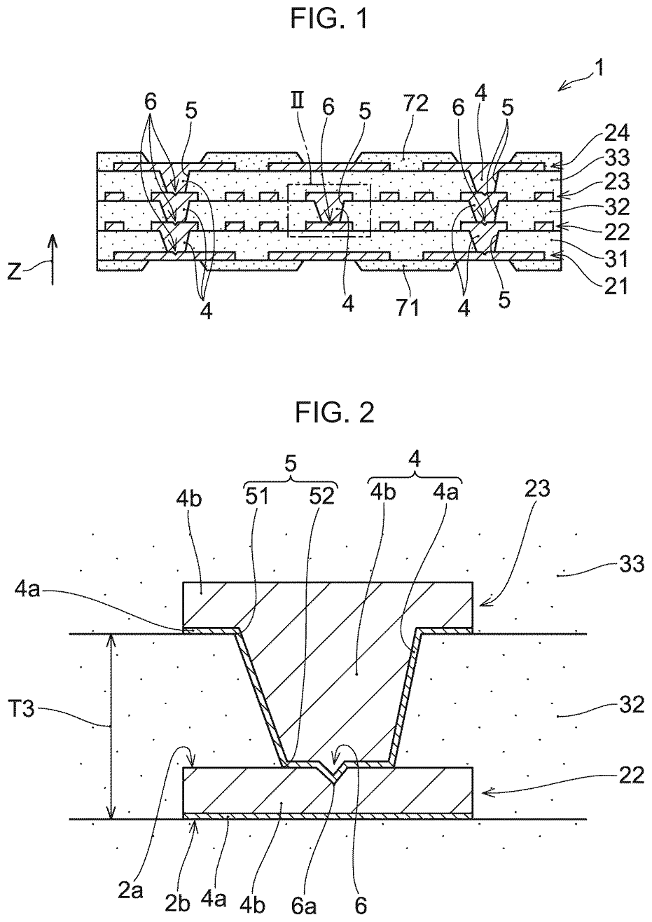

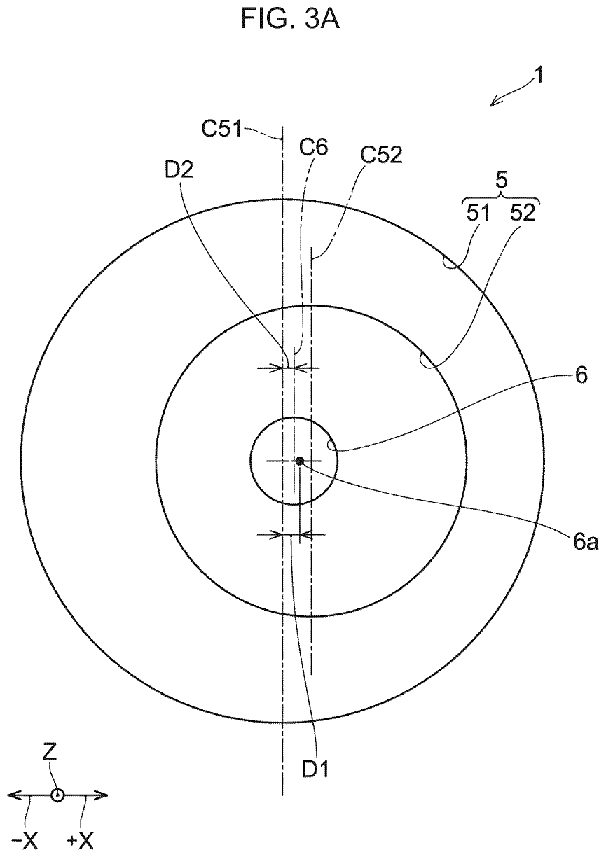

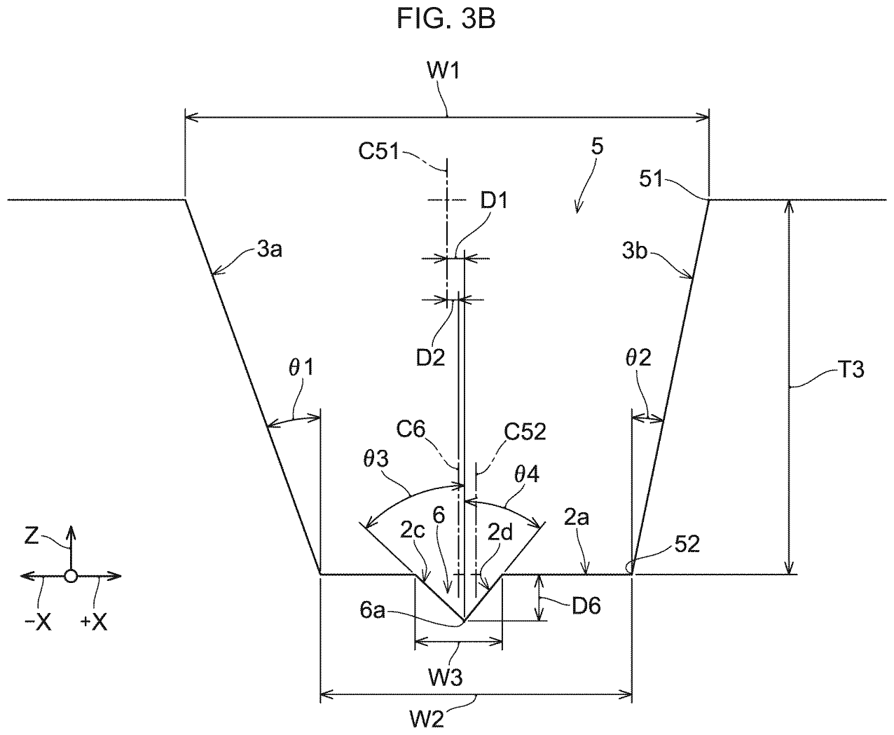

A wiring substrate according to an embodiment of the present invention is described with reference to the drawings. FIG. 1 illustrates a wiring substrate 1, which is an example of a wiring substrate according to an embodiment of the present invention, and FIG. 2 illustrates an enlarged view of a portion (II) of the wiring substrate 1 of FIG. 1. Further, FIG. 3A schematically illustrates a through hole 5 and a recess 6 of the wiring substrate 1 of FIG. 1 in a plan view, and FIG. 3B schematically illustrates cross sections of the through hole 5 and the recess 6.

A laminated structure of the wiring substrate of the embodiment is not limited to the laminated structure of the wiring substrate illustrated in the drawings, and the number of conductor layers and the number of insulating layers included in the wiring substrate of the embodiment are not limited to the number of conductor layers and the number of insulating layers included in the wiring substrate illustrated in the drawings. The wiring substrate of the embodiment may include, in addition to the insulating layers and conductor layers included in the wiring substrate illustrated in the drawings, any number of insulating layers and conductor layers, and it is also possible that all of the insulating layers and conductor layers included in the wiring substrate illustrated in the drawings are not included. In the drawings to be referenced in the following description, in order to facilitate understanding of the embodiment to be disclosed, a specific portion may be depicted in an enlarged manner. Therefore, it may be possible that structural elements are not depicted in precise proportions in terms of size or length relative to each other.

As illustrated in FIG. 1, the wiring substrate 1 includes conductor layers (21-24) and insulating layers (31-33). The conductor layers (21-24) and the insulating layers (31-33) are alternately laminated. A lamination direction of these conductor layers and insulating layers is a thickness direction of the wiring substrate 1, and is hereinafter also referred to as a “Z direction.” In FIG. 1, the insulating layer 31 is laminated to cover one of two surfaces of the conductor layer 21 orthogonal to the Z direction, and on a side of the insulating layer 31 opposite to the conductor layer 21, the conductor layer 22, the insulating layer 32, the conductor layer 23, the insulating layer 33, and the conductor layer 24 are laminated in this order. The insulating layer 32 covers the conductor layer 22, and the insulating layer 33 covers the conductor layer 23. The wiring substrate 1 of the embodiment further includes through holes 5 penetrating the insulating layers (31-33), and via conductors 4 respectively formed in the through holes 5.

In the wiring substrate 1 of FIG. 1, the through holes 5 and the via conductors 4 each have a width that is smaller on the conductor layer 21 side than on the conductor layer 24 side. In the above and following descriptions of the wiring substrate of the embodiment, the side where the width of each of the through holes 5 and the via conductors 4 is greater is also referred to the an “upper side,” and the side where it is smaller is also referred to as the “lower side.” That is, in the wiring substrate 1, the conductor layer 24 side is also referred to as an “upper side,” and the conductor layer 21 side is also referred to as a “lower side.” Therefore, in each of the conductor layers and insulating layers, a surface facing away from the conductor layer 21 or toward the conductor layer 24 is also referred to as an “upper surface,” and a surface facing away from the conductor layer 24 or toward the conductor layer 21 is also referred to as a “lower surface.” The “width” of each of the through holes 5 and the via conductors 4 is a maximum distance between any two points on an outer periphery of the through hole 5 or the via conductor 4 in any cross-sectional plane orthogonal to the Z direction.

As illustrated in FIG. 2, each through hole 5 has a first opening 51 that opens at its upper end and a second opening 52 that opens at its lower end. The second opening 52 faces the conductor layer on the lower side of the through hole 5. Each through hole 5 has a first opening 51 on the opposite side with respect to the conductor layer on its lower side. Therefore, in FIG. 2, each through hole 5 penetrating the insulating layer 32 has a second opening 52 facing the conductor layer 22 and a first opening 51 on the conductor layer 23 side, which is on the opposite side with respect to the conductor layer 22. Similarly, in FIG. 1, each through hole 5 penetrating the insulating layer 31 has a second opening facing the conductor layer 21 and a first opening on the conductor layer 22 side, which is on the opposite side with respect to the conductor layer 21. Each through hole 5 penetrating the insulating layer 33 has a second opening facing the conductor layer 23 and a first opening on the conductor layer 24 side, which is on the opposite side with respect to the conductor layer 23. The through holes 5 and the via conductors 4 in the example of FIGS. 1 and 2 each have a tapered shape that narrows toward the lower side. Therefore, the second opening 52 is smaller than the first opening 51.

Each via conductor 4 formed in a through hole 5 penetrating one of the insulating layers (31-33) is integrally formed with a conductor layer on its upper side and is connected to a conductor layer on its lower side. In FIG. 2, a via conductor 4 formed in a through hole 5 penetrating the insulating layer 32 is integrally formed with the conductor layer 23 on the upper side of the via conductor 4 and is connected to the conductor layer 22 on the lower side of the via conductor 4. The via conductor 4 illustrated in FIG. 2 connects the conductor layer 23 and the conductor layer 22. Similarly, in FIG. 1, a via conductor 4 formed in a through hole 5 penetrating the insulating layer 31 is integrally formed with the conductor layer 22 and is connected to the conductor layer 21, thereby connecting the conductor layer 22 and the conductor layer 21. Further, a via conductor 4 formed in a through hole 5 penetrating the insulating layer 33 is integrally formed with the conductor layer 24 and is connected to the conductor layer 23, thereby connecting the conductor layer 24 and the conductor layer 23.

The wiring substrate 1 of FIG. 1 further includes a solder resist 71 covering the lower surface of the conductor layer 21 and the lower surface of the insulating layer 31, as well as a solder resist 72 covering the upper surface of conductor layer 24 and the upper surface of the insulating layer 33. The solder resists (71, 72) are formed of, for example, a photosensitive epoxy resin. Each of the solder resists has openings formed to expose predetermined regions of the conductor layer 21 or the conductor layer 24.

The conductor layers (21-24) and the via conductors 4 are each formed of any metal having appropriate conductivity. Examples of materials for these conductive structural elements include copper, nickel, gold, titanium, palladium, tungsten, and the like. However, the materials for the conductor layers (21-24) and the via conductors 4 are not limited to these metals alone.

In FIG. 1, the conductor layers (21-24) and the via conductors 4 are depicted in a simplified manner as being each composed of only one layer, but as illustrated in FIG. 2, they may each have a multilayer structure composed of two or more metal films. In the example of FIG. 2, the conductor layer 22 and the conductor layer 23, as well as the via conductors 4, are each composed of a lower layer formed of a metal film (4a) and an upper layer formed of a plating film (4b). The metal film (4a) may be, for example, an electroless plating film or a sputtering film of copper, and the plating film (4b) may be, for example, an electrolytic plating film of copper.

The insulating layers (31-33) are primarily formed of any insulating resin. Examples of the insulating resin used to form the insulating layers (31-33) include epoxy resin, bismaleimide triazine resin (BT resin), phenol resin, fluororesin, liquid crystal polymer (LCP), acrylic resin, fluorinated ethylene (PTFE) resin, polyester (PE) resin, and modified polyimide (MPI) resin. The insulating layers (31-33) may, for example, contain an inorganic filler (not illustrated) made of, for example, silicon oxide or alumina, for adjusting various properties, such as thermal expansion coefficient. Further, the insulating layers (31-33) may contain a core material (not illustrated) made of glass fiber or the like for improving mechanical strength and the like. The resins listed above as materials for the insulating layers (31-33) are merely examples of materials capable of forming the insulating layers. The insulating layers can be formed of any material capable of providing insulation to the conductor layers (21-24) and supporting the conductor layers (21-24).

In the wiring substrate 1 of the embodiment, a surface (2a) on an upper via conductor 4 side of each of the conductor layers (21-23) has a recess 6. That is, recesses 6 are formed on the upper surfaces of the conductor layers (21-23). Each recess 6 has a conical shape that tapers toward the opposite side with respect to a via conductor 4 on the upper side of each of the conductor layers (21-23). That is, as illustrated in FIG. 2, each recess 6 has a tapered shape that narrows from the upper surface (2a) toward the lower surface (2b) side of each conductor layer. Each recess 6 has a tip (6a) facing the opposite side with respect to the through hole 5 on the upper side. The tip (6a) is the deepest part of the recess 6 and is a portion farthest from the surface (2a) on an inner wall surface of the conductor layer exposed in the recess 6. The tip (6a) may be pointed, as in the example of FIG. 2, or may be somewhat rounded.

In each insulating layer, such as the insulating layer 32, a blind hole is formed by a through hole 5 and a conductor layer, such as the conductor layer 22. A bottom surface of the blind hole is constituted by the surface (2a) of the conductor layer. Each recess 6 is formed in a portion of the surface (2a) of the conductor layer that blocks the second opening 52 of the through hole 5, that is, a portion exposed in the through hole 5. Therefore, the recess 6 itself is also exposed in the through hole 5. The recess 6 is smaller than the second opening 52 of the through hole 5 in a plan view. Therefore, in each through hole 5, not only a recess 6 but also a portion of the surface (2a) of the conductor layer is exposed.

The recesses 6 respectively communicate with the through holes 5 on the upper sides of the conductor layers (21-23). That is, the through holes 5 are respectively in communication with the recesses 6. Therefore, the recesses 6 are also respectively filled with the via conductors 4. Therefore, each via conductor 4 is also partially formed in a recess 6, extending into the recess. As illustrated in FIG. 3A, each recess 6 is formed, in a plan view, at a position overlapping with a through hole 5 on the upper side of the recess 6. The term “plan view”means viewing an object along the Z direction.

In the wiring substrate 1 of the embodiment, as illustrated in FIGS. 3A and 3B, a center (C6) of the recess 6 on the surface (2a) of a conductor layer is offset, in a plan view, relative to a center (C51) of the first opening 51 of the through hole 5. The term “offset” regarding the center (C6) of the recess 6 relative to the center (C51) of the first opening 51 in a plan view means that, in the plan view, the position of the center (C6) is misaligned with the position of the center (C51). That is, in the wiring substrate 1, the center (C6) and the center (C51) do not overlap in a plan view. The first opening 51 is eccentric, in a plan view, with respect to the center (C6) of the recess 6 on the surface (2a) of the conductor layer. In other words, the recess 6 is eccentric, on the surface (2a) of the conductor layer, with respect to the center (C51) of the first opening 51 in a plan view. In the example of FIGS. 3A and 3B, the center (C6) of the recess 6 is formed, in each figure, on a first direction side (right side) indicated by an arrow (X) (hereinafter, the first direction is also referred to as the “+X direction”) relative to the center (C51) of the first opening 51. The “+X direction” and a “-X direction” to be described later are directions orthogonal to the Z direction. The direction in which the position of the center (C6) is offset relative to the position of the center (C51) does not need to be limited to a specific direction and may be any direction orthogonal to the Z direction.

As will be described later, in the wiring substrate of the embodiment, the recesses 6 that respectively communicate with the through holes 5 are formed concurrently with the formation of the through holes 5 during the formation of the through holes 5. The through holes 5 in the wiring substrate 1 of the embodiment are, in one example, formed by laser beam irradiation. By appropriately refracting or reflecting the laser beam used for forming the through holes 5, a center of a spot of the laser beam traveling along the Z direction in each insulating layer, such as the insulating layer 32, can be shifted in a specific direction as the laser beam progresses. By shifting the center of the spot in this manner, it is possible to form a through hole 5 having a first opening 51 and a second opening 52 whose centers are offset from each other in a plan view.

Further, for example, by using reflection or refraction of a laser beam to focus the laser beam at a predetermined position, power at a central part of the spot of the laser beam can be enhanced. That is, in the formation of the through holes 5, the power at the central part of the spot of the laser beam passing through each insulating layer can be enhanced at the surface (2a) of each conductor layer. Therefore, at the surface (2a), a recess 6 is easily formed at the central part of the spot of the laser beam irradiating the surface (2a). That is, a recess 6 is easily formed at a central part of the second opening 52. As a result, a recess 6 can be formed on the surface (2a) of each conductor layer, with its center (C6) offset relative to the center (C51) of the first opening 51 in a plan view.

In this way, in the wiring substrate 1 of the embodiment, a recess 6, which communicates with a through hole 5 in which a via conductor 4 (see FIGS. 1 and 2) is formed, is formed on the surface (2a) of each conductor layer, such as the conductor layer 22. The via conductor 4 is also formed in the recess 6, and within the recess 6, it is in contact with an inner wall surface of the conductor layer, such as the conductor layer 22. That is, a contact area between each via conductor 4 and a conductor layer is large. Therefore, compared to the case where the recess 6 is not formed, it is considered that adhesion between a via conductor 4 and a conductor layer, such as the conductor layer 22, is higher. Therefore, it is considered that peeling of the via conductor 4 from the conductor layer is less likely to occur.

Further, in the wiring substrate 1 of the embodiment, since the center (C6) of the recess 6 is offset relative to the center (C51) of the first opening 51 of the through hole 5 in a plan view, misalignment between the via conductor 4 and each conductor layer, such as the conductor layer 22, and each insulating layer, such as the insulating layer 32, is less likely to occur. That is, since the via conductor 4 extends into the recess 6, which is eccentric relative to the center (C51) of the first opening 51 in a plan view, the via conductor 4 is less likely to rotate along a direction (circumferential direction) around a periphery of the via conductor 4 in a plan view. Such rotational movement along the circumferential direction is prevented by the portion of the via conductor 4 that extends into the recess 6, due to the center (C6) being offset relative to the center (C51). Therefore, even when a force is applied along the circumferential direction of the via conductor 4 in a plan view, the via conductor 4 is less likely to move relative to each conductor layer and each insulating layer. As a result, it is considered that peeling of the via conductor 4 from each conductor layer is less likely to occur.

In this way, in the wiring substrate of the embodiment, the recess 6 having the center (C6) offset in a plan view relative to the center (C51) of the first opening 51 of the through hole 5 is formed on the surface (2a) of each conductor layer, such as conductor layer 22. Therefore, it is considered that peeling of the via conductor 4 is suppressed. As a result, it is considered that internal connection reliability of the wiring substrate of the embodiment is improved.

### Relationship Between Shape Characteristics of Through Holes and Shape Characteristics of Recesses

As described above, the recesses 6 of the wiring substrate of the embodiment are formed concurrently with the formation of the through holes 5. Therefore, the recesses 6 may have characteristics similar to those of the through holes 5 with respect to shape. Several of these characteristics are described below with continued reference to FIGS. 3A and 3B, which schematically illustrate a through hole 5 and a recess 6.

In FIGS. 3A and 3B, a center (C52) of the second opening 52 of the through hole 5 is offset in the first direction (+X direction) relative to the center (C51) of the first opening 51 in a plan view. That is, in a plan view, the position of the center (C52) is shifted in the +X direction relative to the position of the center (C51). The second opening 52 is eccentric in the +X direction relative to the center (C51) of the first opening 51 in a plan view, or in other words, the first opening 51 is eccentric in a second direction, opposite to the first direction, relative to the center (C52) of the second opening 52 in a plan view.

Hereinafter, the second direction is also referred to as the “−X direction,” and when the distinction of direction is unnecessary, the “+X direction” and “−X direction” are collectively referred to simply as the “X direction.”

Further, the tip (6a) of each recess 6 is offset in the +X direction in a plan view relative to the center (C6) of the recess 6 on the surface (2a) of each conductor layer, such as the conductor layer 22 (see FIG. 2). That is, in a plan view, the position of the tip (6a) is shifted in the +X direction relative to the position of the center (C6). The tip (6a) of the recess 6 is eccentric in the +X direction relative to the center (C6) of the recess 6 on the surface (2a) in a plan view, or in other words, the recess 6 on the surface (2a) is eccentric in the-X direction relative to the tip (6a) in a plan view.

That is, a central axis of the through hole 5 is tilted relative to the Z direction such that it shifts in the +X direction toward the second opening 52 side, and a central axis of the recess 6 is also tilted relative to the Z direction such that it shifts in the +X direction toward the tip (6a) side. In this way, as schematically illustrated in FIGS. 3A and 3B, each recess 6 in the example of FIGS. 1 and 2 has characteristics similar to those of each through hole 5 with respect to the central axis.

Further, as described above, the center (C6) of the recess 6 on the surface (2a) of each conductor layer is offset in a plan view relative to the center (C51) of the first opening 51 of the through hole 5, and the tip (6a) of the recess 6 is offset in a plan view relative to the center (C6) of the recess 6. Therefore, the tip (6a) of the recess 6 may also be offset in a plan view relative to the center (C51) of the first opening 51. As illustrated in FIGS. 3A and 3B, when the direction in which the center (C6) is offset relative to the center (C51) is the same as the direction in which the tip (6a) is offset relative to the center (C6), the tip (6a) of the recess 6 is also offset relative to the center (C51) in a plan view. In this case, an offset (D1) of the tip (6a) relative to the center (C51) of the first opening 51 is greater than an offset (D2) of the center (C6) of the recess 6 on the surface (2a) of each conductor layer relative to the center (C51) of the first opening 51. When the offset (D1) is greater than the offset (D2), it is considered that the via conductor 4 is even less likely to move relative to each conductor layer and each insulating layer. As a result, it is considered that peeling of the via conductor 4 from each conductor layer is even less likely to occur.

As illustrated in FIG. 3B, the through hole 5 has a tapered shape that narrows toward the lower side, and the second opening 52 is eccentric relative to the first opening 51 in a plan view. Therefore, an inclination angle of the inner wall surface of each insulating layer exposed to the through hole 5 varies along a circumferential direction of the through hole 5. That is, in FIG. 3B, a first wall surface (3a) and a second wall surface (3b) facing each other within the through hole 5 may be inclined at different angles.

Similarly, the recess 6 has a tapered shape that narrows toward the lower side, and the tip (6a) is offset in a plan view relative to the center (C6) of the recess 6 on the surface (2a) of each conductor layer. Therefore, an inclination angle of the inner wall surface of each conductor layer exposed to the recess 6 varies along a circumferential direction of the recess 6. That is, in FIG. 3B, a third wall surface (2c) and a fourth wall surface (2d) facing each other within the recess 6 may be inclined at different angles.

Then, in FIG. 3B, when an angle (θ1) (first angle) of the first wall surface (3a) of each insulating layer relative to the Z direction is greater than an angle (θ2) (second angle) of the second wall surface (3b) of each insulating layer relative to the Z direction, an angle (θ3) (third angle) of the third wall surface (2c) of each conductor layer relative to the Z direction is greater than an angle (θ4) (fourth angle) of the fourth wall surface (2d) of each conductor layer relative to the Z direction. On the other hand, when the angle (θ2) is greater than the angle (θ1), the angle (θ4) is greater than the angle (θ3).

That is, in a cross section of the wiring substrate 1 along the Z direction, taken along a cutting line passing through the center of the through hole 5 (hereinafter, this cross section is also referred to as the “first cross section”), the first wall surface (3a) of the two wall surfaces (3a, 3b) of each insulating layer facing each other across the through hole 5 has the angle (θ1) relative to the Z direction, and the second wall surface (3b) has the angle (θ2) relative to the Z direction. Specifically, the first cross section is a cross section taken along a cutting line passing through the center (C51) of the first opening 51 and the center (C52) of the second opening 52. On the other hand, in the first cross section, the third wall surface (2c) of the two wall surfaces (2c, 2d) of each conductor layer facing each other across the recess 6, formed on the first wall surface (3a) side, has the angle (θ3) relative to the Z direction, and the fourth wall surface (2d), formed on the second wall surface (3b) side, has the angle (θ4) relative to the Z direction.

In the example of FIG. 3A, the angle (θ1) is greater than the angle (θ2), and therefore, the angle (θ3) is greater than the angle (θ4). On the other hand, in contrast to the example of FIG. 3A, the angle (θ2) may be greater than the angle (θ1), and in this case, the angle (θ4) is greater than the angle (θ3). By establishing such a relationship in the magnitudes of the angles (θ1) to (θ4), it is easy to offset the center (C6) of the recess 6 on the surface (2a) of each conductor layer relative to the center (C51) of the first opening 51 in a plan view. Further, the offset (D1) of the tip (6a) of the recess 6 relative to the center (C51) of the first opening 51 can be made greater than the offset (D2) of the center (C6) of the recess 6 on the surface (2a) relative to the center (C51) of the first opening 51.

### Examples of Dimensions Around Through Hole and Recess

A thickness (T3) of an insulating layer that a through hole 5 penetrates (a distance between the upper and lower conductor layers sandwiching the insulating layer) is, for example, 5 μm or more and 15 μm or less. A width (W1) of a through hole 5 at the upper surface of each insulating layer (a width of the first opening 51) is, for example, 5 μm or more and 15 μm or less, and a width (W2) of the through hole 5 at the lower surface of each insulating layer (a width of the second opening 52) is, for example, 2 μm or more and 10 μm or less. A via conductor 4 having a small diameter and short length can be provided. In particular, in the wiring substrate 1 of the embodiment, since the via conductors 4 (see FIG. 1) are less likely to peel from the conductor layers, even for small-diameter via conductors 4, problems such as open failures or increases in electrical resistance between the via conductors 4 and the conductor layers are unlikely to occur.

A width (W3) of each recess 6 on the surface (2a) of each conductor layer is 1 μm or more and 5 μm or less. A depth (D6) of each recess 6 is 1 μm or more and 5 μm or less. The angle (θ1) and the angle (θ2) are, for example, 10° or more and 30° or less, and a difference between the angle (θ1) and the angle (θ2) is, for example, 0° or more and 10° or less in absolute value. Further, the angle (θ3) and the angle (θ4) are, for example, 40° or more and 55° or less, and a difference between the angle (θ3) and the angle (θ4) is, for example, 0° or more and 10° or less in absolute value.

The angles (θ1 to θ4) are determined with respect to the first cross section. The angle (θ1) is determined by the arctangent of (a distance in the X direction between an outer edge of the first opening 51 and an outer edge of the second opening 52 on the first wall surface (3a) side)/(the thickness (T3) of the insulating layer). Similarly, the angle (θ2) is determined by the arctangent of (a distance in the X direction between an outer edge of the first opening 51 and an outer edge of the second opening 52 on the second wall surface (3b) side)/(the thickness (T3) of the insulating layer). Further, the angle (θ3) is determined by the arctangent of (a distance in the X direction between an outer edge of the recess 6 on the third wall surface (2c) side at the surface (2a) of each conductor layer and the tip (6a) of the recess 6)/(the depth (D6) of the recess 6). The angle (θ4) is determined by the arctangent of (a distance in the X direction between an outer edge of the recess 6 on the fourth wall surface (2d) side at the surface (2a) of each conductor layer and the tip (6a) of the recess 6)/(the depth (D6) of the recess 6).

### Method for Manufacturing Wiring Substrate

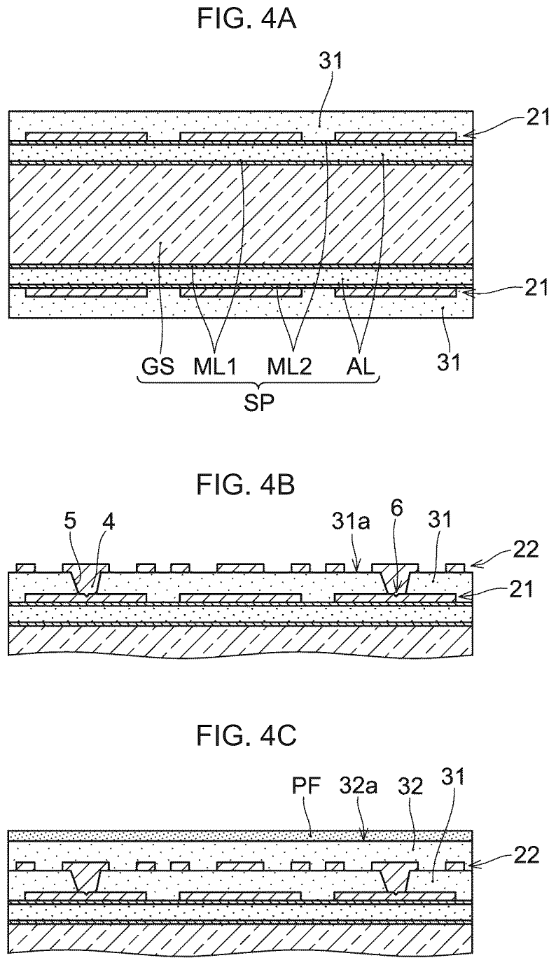

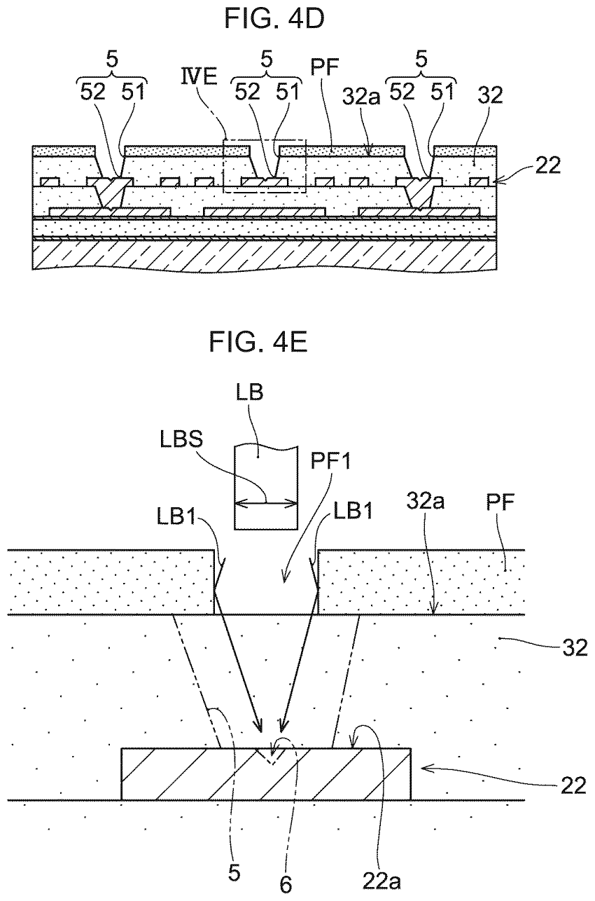

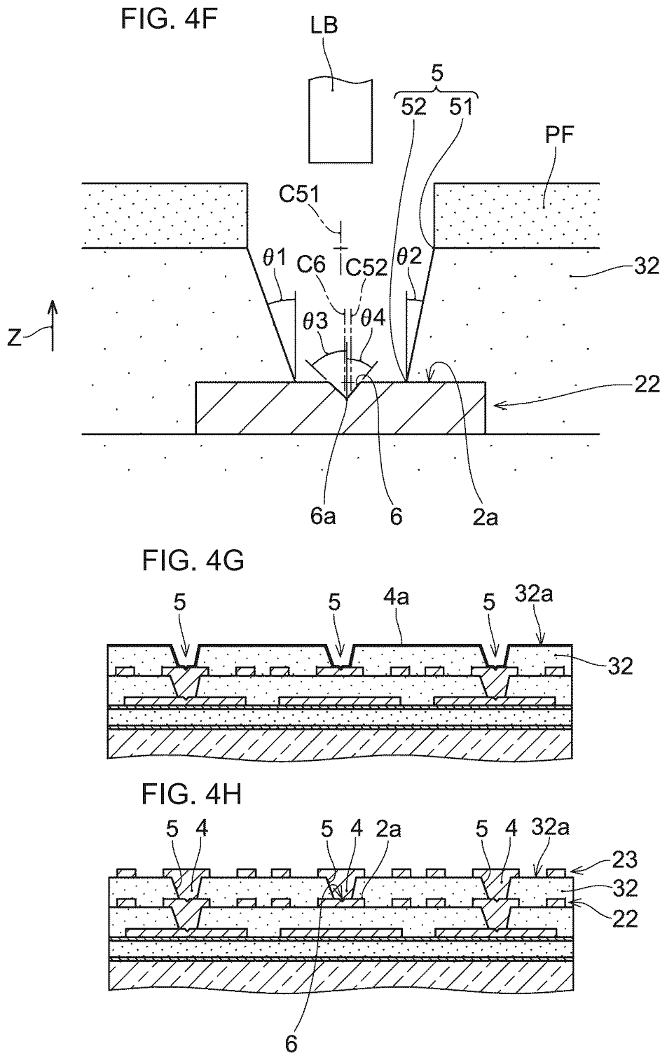

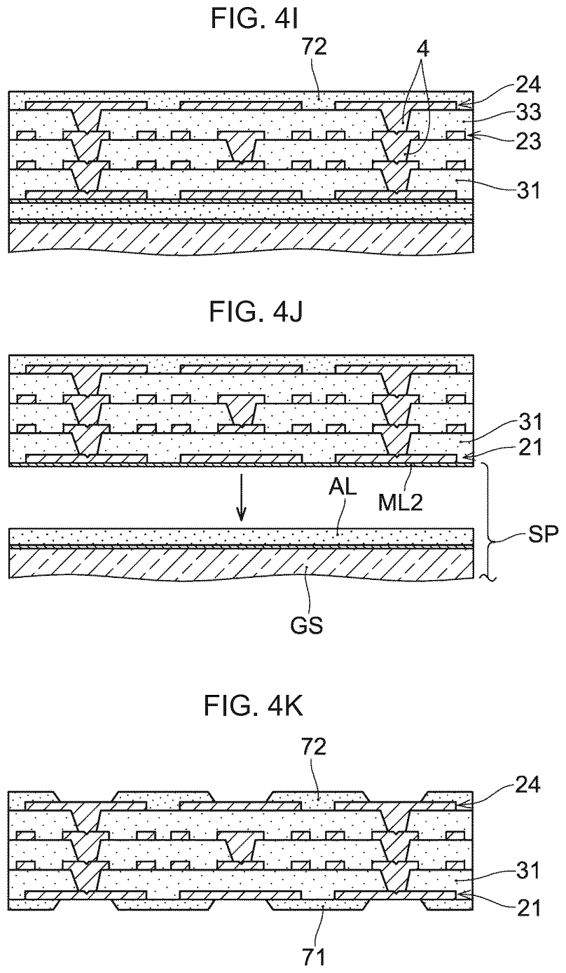

With reference to FIGS. 4A-4K, a method for manufacturing the wiring substrate of the embodiment is described using the wiring substrate 1 illustrated in FIG. 1 as an example.

As illustrated in FIG. 4A, a support substrate (SP) is prepared, which includes a core layer (GS) and metal film layers (ML1, ML2) laminated on each of two surfaces of the core layer (GS). The core layer (GS) is composed of, for example, a glass material or a glass-epoxy material. The metal film layers (ML1, ML2) are each, for example, a single-layer or multilayer metal film formed by electroless plating or sputtering using materials such as copper and titanium. The metal film layer (ML1) and the metal film layer (ML2) are bonded together by, for example, an adhesive layer (AL) composed of an adhesive whose adhesiveness changes upon exposure to light.

In the following description, a side closer to the core layer (GS) of the support substrate (SP) is also referred to as “lower” or “lower side,” and a side farther from the core layer (GS) is also referred to as “upper” or “upper side.” Therefore, of each of the elements constituting the wiring structure, a surface facing the support substrate (SP) is also referred to as a “lower surface,” and a surface facing the opposite side with respect to the support substrate (SP) is also referred to as an “upper surface.”

The conductor layer 21 is formed on the metal film layer (ML2) on both surfaces of the prepared support substrate (SP). In the formation of the conductor layer 21, for example, a plating resist (not illustrated) having predetermined openings is formed on the metal film layer (ML2). By electrolytic plating using the metal film layer (ML2) as a power feeding layer, a plating film is deposited in the openings of the plating resist. After that, the plating resist is removed. The conductor layer 21, including conductor patterns formed of the plating film deposited in the openings of the plating resist, is formed.

After the formation of the conductor layer 21, the insulating layer 31 covering the conductor layer 21 is formed. The insulating layer 31 is formed of an insulating resin such as epoxy resin, BT resin, or phenol resin. In the formation of the insulating layer 31, for example, a film made of an insulating resin such as epoxy resin is laminated on the conductor layer 21 and the metal film layer (ML2). The laminated resin film is thermocompression bonded to the conductor layer 21 and the metal film layer (ML2), for example, by heating and pressing, thereby forming the insulating layer 31.

As illustrated in FIG. 4B, the conductor layer 22 is formed on the insulating layer 31. Further, the through holes 5 are formed in the insulating layer 31, and the via conductors 4 are formed in the through holes 5. In FIG. 4B, as well as in FIGS. 4C, 4D, and 4G to 4J to be referenced later, only one surface side of the support substrate (SP) is illustrated, and illustration of a state on the other side is omitted. However, on the surface of the support substrate (SP) on the side where illustration is omitted, insulating layers and conductor layers may be formed in the same manner as on the illustrated side, or it is also possible that such conductor layers and insulating layers are not formed.

The conductor layer 22 and the via conductors 4 are basically formed using a semi-additive method, but specifically, they are formed using a method similar to the method for forming the conductor layer 23 and the via conductors 4 to be described with reference to FIGS. 4C to 4H. Therefore, similar to the conductor layer 22 in FIG. 4H, in FIG. 4B as well, the recesses 6 are formed on the upper surface of the conductor layer 21 in contact with the via conductors 4. Although not illustrated, a protective film (PF), as illustrated in FIG. 4C, may be provided on an upper surface (31a) of the insulating layer 31 after the formation of the insulating layer 31 and before the formation of the through holes 5. A specific method for forming the through holes 5, including the formation of the recesses 6, is described below with reference to FIGS. 4C to 4F, using the formation of the through holes 5 in the insulating layer 32 as an example.

As illustrated in FIG. 4C, the insulating layer 32 covering the upper surfaces of the conductor layer 22 and the insulating layer 31 is formed. The insulating layer 32 is formed, for example, in the same manner as the insulating layer 31, by thermocompression bonding a resin film having appropriate insulating properties, such as an epoxy resin. The method for manufacturing the wiring substrate of the embodiment thus includes forming the conductor layer 22 and forming the insulating layer 32 covering the conductor layer 22.

In the example of FIG. 4C, a protective film (PF) is provided on an upper surface (32a), which is a surface of the insulating layer 32 facing away from the conductor layer 22. The protective film (PF) is bonded to the upper surface (32a) of the insulating layer 32, for example, via an optional adhesive layer (not illustrated). The protective film (PF) may be provided on the upper surface (32a) after the formation of the insulating layer 32, or it may be provided on one surface of the resin film used to form the insulating layer 32 before the formation of the insulating layer 32. In the method for manufacturing the wiring substrate of the embodiment, the forming of the insulating layer 32 may include, as in the example of FIG. 4C, forming a resin layer as the insulating layer 32 with a protective film (PF) provided on a surface on the opposite side with respect to the conductor layer 22.

For the formation of the protective film (PF), a material with a high refractive index and optical transparency may be preferable in relation to the formation of the recesses 6 (see FIG. 4D). Examples of materials for the protective film (PF) include resins such as polyethylene naphthalate (PEN) and polyethylene terephthalate (PET). Therefore, the protective film (PF) may conatin polyethylene naphthalate or polyethylene terephthalate. Optical properties of polyethylene naphthalate may facilitate the formation of the conical-shaped recesses 6.

As illustrated in FIG. 4D, the through holes 5 are formed in the insulating layer 32. The through holes 5 penetrating the insulating layer 32 each have a first opening 51 that opens toward the upper side and a second opening 52 that opens toward the lower side. That is, the through holes 5 are formed, each having a first opening 51 that opens toward the opposite side with respect to the conductor layer 22 and a second opening 52 that opens toward the conductor layer 22. The through holes 5 are formed, each having a tapered shape with the second opening 52 smaller than the first opening 51. In FIG. 4D, since the protective film (PF) is formed on the upper surface (32a) of the insulating layer 32, the through holes 5 are formed to penetrate the protective film (PF) as well.

The formation of the through holes 5 is described in more detail with reference to FIGS. 4E and 4F. FIGS. 4E and 4F each illustrate an enlarged view of a state of a portion (IVE) illustrated in FIG. 4D during a formation process of a through hole 5. FIG. 4E illustrates a state of the portion (IVE) at an initial stage of the formation process of the through hole 5, and FIG. 4F illustrates a state immediately after the formation of the through hole 5.

As illustrated in FIG. 4E, a laser beam (LB) is irradiated onto a location in the insulating layer 32 where a through hole 5 is to be formed. By irradiating the insulating layer 32 with the laser beam (LB), an irradiated portion and its vicinity in the insulating layer 32 are sublimated, forming a through hole 5 in the sublimated portion. As the laser beam (LB) for forming the through holes 5, a laser beam having high directivity and capable of having large power is preferable. By using a laser beam (LB) with such characteristics, it becomes possible to form through holes 5 having widths that are relatively small compared to the thickness of the insulating layer 32. An example of a laser beam (LB) particularly suitable for forming such through holes 5 is an ultraviolet (UV) laser beam. Therefore, in the method for manufacturing the wiring substrate of the embodiment, the forming of the through holes 5 may include irradiating a laser beam in an ultraviolet band as the laser beam (LB). The laser beam (LB) used for forming the through holes 5 may also be a laser beam from a source other than the UV laser, such as a carbon dioxide laser beam or a YAG laser beam.

In the example of FIG. 4E, since the protective film (PF) is formed on the upper surface (32a) of the insulating layer 32, the laser beam (LB) first irradiates the protective film (PF). In the method for manufacturing the wiring substrate of the embodiment, the forming of the through holes 5 may include, as illustrated in FIG. 4E, irradiating the laser beam (LB) toward the protective film (PF). By irradiating the insulating layer 32 with the laser beam (LB) through the protective film (PF) instead of directly irradiating the insulating layer 32 with the laser beam (LB), adhesion of foreign matter to the upper surface (32a) of the insulating layer 32 can be prevented.

When the protective film (PF) is irradiated with the laser beam (LB), an opening (PF1) penetrating the protective film (PF) is first formed in the protective film (PF). After that, a diffusion-direction component (LB1) of the laser beam (LB), which continues to be irradiated, is reflected at a wall surface of the opening (PF1) and enters the insulating layer 32. The diffusion-direction component (LB1) is reflected at the wall surface of the opening (PF1) over the entire circumference of the wall surface of the opening (PF1). Therefore, inside the insulating layer 32, the power of the laser beam (LB) at a central part of a spot (LBS) of the laser beam (LB) is enhanced compared to the power at a peripheral part of the spot (LBS). The laser beam (LB), with enhanced power at the central part of the spot (LBS), irradiates the surface (2a) of the conductor layer 22. Therefore, a portion of the surface (22a) of the conductor layer 22 irradiated by the central part of the laser beam (LB) is sublimated. As a result, a recess 6 is formed on the surface (22a). In the conductor layer 22, sublimation occurs over a larger region on a side closer to the surface (22a) in the thickness direction of the conductor layer 22, resulting in the formation of a recess 6 having a conical shape that tapers toward the opposite side with respect to the surface (22a).

In this way, in the method for manufacturing the wiring substrate of the embodiment, the irradiating of the laser beam (LB) may include enhancing the power at the central part of the spot (LBS) of the laser beam (LB) more than at the peripheral part of the spot (LBS). For example, by enhancing the power at the central part of the laser beam that can have large power, such as a UV laser beam, a part of a surface of a conductor layer formed of a metal such as copper can be sublimated to form a recess.

Further, by providing the protective film (PF) on the upper surface (32a) of the insulating layer 32 and utilizing the opening (PF1) formed in the protective film (PF) by irradiation with the laser beam (LB), the power at the central part of the spot (LBS) of the laser beam (LB) can be easily enhanced.

The diffusion-direction component (LB1) of the laser beam (LB) typically cannot be incident on the wall surface of the opening (PF1) at a uniform angle over the entire circumference. As a result, the reflected light of the diffusion-direction component (LB1) is unlikely to occur at a uniform reflection angle over the entire circumference of the opening (PF1). Therefore, the power of the laser beam (LB) is enhanced at a position offset in a plan view from the center of the spot (LBS) of the laser beam (LB). On the other hand, the opening (first opening) of the through hole 5 formed on the upper surface (32a) of the insulating layer 32 is formed at substantially the same position as the spot (LBS) of the laser beam (LB) in a plan view, because the reflected light from the wall surface of the opening (PF1) cannot yet converge at the upper surface (32a).

As a result, as illustrated in FIG. 4F, a recess 6 having a center (C6) at a position offset in a plan view relative to the center (C51) of the first opening 51 is formed on the surface (2a) of the conductor layer 22. In this way, in the method for manufacturing the wiring substrate of the embodiment, the forming of a through hole 5 includes forming, on a surface (2a) of the conductor layer 22 on the insulating layer 32 side, a recess 6 having a conical shape that tapers toward the opposite side with respect to the through hole 5. The center (C6) of the recess 6 on the surface (2a) of the conductor layer 22 is offset, in a plan view, relative to the center (C51) of the first opening 51 of the through hole 5. By forming such a recess 6, it is possible to make peeling of a via conductor 4 (see FIG. 4H), which is formed in a subsequent process, from the conductor layer 22 less likely to occur. That is, as described in the description about the wiring substrate of the embodiment, since a via conductor 4 formed in a subsequent process partially extends into the recess 6, which is eccentric in a plan view relative to the center (C51) of the first opening 51, the via conductor 4 is less likely to rotate along a circumferential direction. Therefore, the via conductor 4 is less likely to move relative to the conductor layer 22 and the insulating layer 32. That is, it is considered that peeling of the via conductor 4 from the conductor layer 22 is less likely to occur.

In the method for manufacturing the wiring substrate of the embodiment, through the formation of a through hole 5, a recess 6 is formed on the surface (2a) of the conductor layer 22 exposed in the through hole 5. That is, the recess 6 is not formed in a separate process or by separate means after the formation of the through hole 5. Instead, the through hole 5 and the recess 6 are formed through a series of treatments, such as irradiation with the laser beam (LB), within the same process. In this way, in the method for manufacturing the wiring substrate of the embodiment, the recess 6, which can contribute to preventing peeling of the via conductor 4, is formed in the process of forming the through hole 5, through the formation of the through hole. Therefore, the recess 6 can be formed easily in a short time. Therefore, according to the method for manufacturing the wiring substrate of the embodiment, it is considered that a wiring substrate with good internal connection reliability can be more easily manufactured compared to the conventional art.

In this way, the through hole 5 and the recess 6 formed through a series of treatments are formed to have similar characteristics with respect to shape. For example, the through hole 5 and the recess 6, both having tapered shapes, can have specific relationships with respect to the angles of their wall surfaces relative to the Z direction.

That is, in the cross section illustrated in FIG. 4F, when the angle (θ1) of one wall surface among the two wall surfaces of the insulating layer 32 facing each other across the through hole 5 is greater than the angle (θ2) of the other wall surface, the angle (θ3) on the same side as the angle (θ1), among the two angles of the respective two wall surfaces of the conductor layer 22 facing each other across the recess 6, is greater than the angle (θ4) on the same side as the angle (θ2). On the other hand, when the angle (θ2) is greater than the angle (θ1), the angle (θ4) is greater than the angle (θ3). In FIG. 4F, the angle (θ1) is greater than the angle (θ2), and thus, the angle (θ3) is greater than the angle (θ4).

Therefore, in FIG. 4F, the tip (6a) of the recess 6 is offset relative to the center (C6) of the recess 6 on the surface (2a) of the conductor layer 22 in the same direction as the offset of the center (C52) of the second opening 52 relative to the center (C51) of the first opening 51 of the through hole 5. Further, the tip (6a) of the recess 6 is offset relative to the center (C51) of the first opening 51 in a plan view, and this offset is greater than the offset of the center (C6) of the recess 6 on the surface (2a) of the conductor layer 22 relative to the center (C51) of the first opening 51.

After the formation of the through hole 5 and the recess 6, the protective film (PF) is removed, for example, using an appropriate stripping agent.

As illustrated in FIG. 4G, for example, the metal film (4a) made of copper is formed on the upper surface (32a) of the insulating layer 32 and in the through holes 5 by electroless plating or sputtering.

As illustrated in FIG. 4H, the conductor layer 23 is formed on the upper surface (32a) of the insulating layer 32. The via conductors 4 are formed in the through holes 5 formed in the insulating layer 32. The via conductors 4 are also formed in the recesses 6 formed on the upper surface (2a) of the conductor layer 22 exposed in the through holes 5. The recesses 6 are filled with the conductive material forming the via conductors 4. The conductor layer 23 is formed using the same method as the conductor layer 21 and the conductor layer 22. For example, the conductor layer 23 is formed using a semi-additive method. That is, a plating resist (not illustrated) having openings corresponding to the conductor patterns included in the conductor layer 23 and openings over the through holes 5 is formed on the metal film (4a) (see FIG. 4G). An electrolytic plating film is deposited in the openings of the plating resist by electrolytic plating using the metal film (4a) as a power feeding layer. The via conductors 4 are formed in the through holes 5. After the formation of the electrolytic plating film, the plating resist is removed, and a portion of the metal film (4a) exposed by the removal of the plating resist is removed, for example, by quick etching. The conductor layer 23, including individual conductor patterns separated from each other, is formed.

As illustrated in FIG. 4I, the insulating layer 33, the conductor layer 24, and the via conductors 4 penetrating the insulating layer 33 are further formed using methods similar to those previously described for forming the insulating layer 31, the conductor layer 23, and the via conductors 4 penetrating the insulating layer 33. Then, the solder resist 72 is formed on the conductor layer 24 and the insulating layer 33. The solder resist 72 is formed, for example, using a photosensitive polyimide resin or epoxy resin, using any method such as spraying, laminating, or coating. The solder resist 72 may be formed after removing the metal film layer (ML2) of the support substrate (SP), as described below, rather than immediately after the formation of the conductor layer 24.

As illustrated in FIG. 4J, the core layer (GS) of the support substrate (SP) is removed. The lower surface of the metal film layer (ML2) of the support substrate (SP) is exposed. The core layer (GS) is removed, for example, by softening the adhesive layer (AL) through laser beam irradiation and then peeling the metal film layer (ML2) from the adhesive layer (AL). Then, the metal film layer (ML2) is removed by etching. The lower surface of the conductor layer 21 and the lower surface of the insulating layer 31 are exposed.

As illustrated in FIG. 4K, the solder resist 71 covering the lower surfaces of the conductor layer 21 and the insulating layer 31 is formed using a method similar to that used for forming the solder resist 72. Openings exposing the conductor layer 21 or the conductor layer 24 are formed in the solder resists (71, 72). The openings in the solder resists (71, 72) are formed, for example, by photolithography including exposure and development processes, or by laser beam irradiation, or the like. Through the above processes, the wiring substrate 1 illustrated in FIG. 1 is completed.

The wiring substrate of the embodiment is not limited to those having the structures illustrated in the drawings and those having the structures, shapes, and materials exemplified in the present specification. As described above, the wiring substrate of the embodiment can have any laminated structure. In the wiring substrate of the embodiment, a recess 6 communicating with a through hole may be formed on a surface of any conductor layer exposed in the through hole. In the wiring substrate of the embodiment, a surface of at least one conductor layer has a recess communicating with a through hole in which a via conductor connected to the conductor layer is formed. The wiring substrate of the embodiment is not necessarily a so-called coreless substrate, such as the wiring substrate 1 illustrated in FIG. 1, and may include a core substrate and build-up layers formed on both surfaces of the core substrate.

The method for manufacturing the wiring substrate of the embodiment is not limited the method described with reference to the drawings. For example, the methods for forming the insulating layers or the conductor layers are not limited to the methods described with reference to FIGS. 4A to 4K. The conductor layers (21-24) may be formed using a method other than a semi-additive method, such as a full-additive method. The insulating layers (31-33) can each be formed using a resin in any form without being limited to a film-like resin. The formation of a recess on a surface of a conductor layer through the formation of a through hole may be performed by other means without using a protective film on the insulating layer. However, as described above, using a protective film makes it easier to form the recess. The protective film may be made of a material other than PEN and PET. In the method for manufacturing the wiring substrate of the embodiment, it is also possible that any process other than the processes described above is added, or some of the processes described above are omitted.

International Publication No. 2020/241645 describes a multilayer wiring substrate in which a first metal wiring layer, an insulating layer, and a second metal wiring layer are laminated. A via hole is formed in the insulating layer, and a recess with a smaller diameter than a lower opening of the via hole is formed on an upper surface of the first metal wiring layer exposed in the via hole. The first metal wiring layer and the second metal wiring layer are electrically connected by a metal layer and a plating layer formed on wall and bottom surfaces of the recess and along a wall surface of the via hole.

In the multilayer wiring substrate disclosed in International Publication No. 2020/241645, strength against a force applied to an interface between the metal layer connecting the first metal wiring layer and the second metal wiring layer and a surface of the first metal wiring layer may not be sufficient. Therefore, peeling may occur at this interface during use of the multilayer wiring substrate. Further, since the recess on the upper surface of the first metal wiring layer in International Publication No. 2020/241645 is formed by etching after the formation of the via hole, a manufacturing process for the multilayer wiring substrate is considered to be long and complicated.

A wiring substrate according to an embodiment of the present invention includes: a conductor layer; an insulating layer covering the conductor layer; a through hole penetrating the insulating layer, having a first opening on the opposite side with respect to the conductor layer and a second opening facing the conductor layer; and a via conductor formed inside the through hole and connecting to the conductor layer. A surface of the conductor layer facing the via conductor has a recess communicating with the through hole. The recess is smaller than the second opening in a plan view and has a conical shape tapering toward the opposite side with respect to the via conductor. A center of the recess on the surface of the conductor layer is offset from the center of the first opening in a plan view.

A method for manufacturing the wiring substrate according to an embodiment of the present invention includes: forming a conductor layer; forming an insulating layer covering the conductor layer; forming a through hole in the insulating layer, the through hole having a first opening facing away from the conductor layer; and forming a via conductor connected to the conductor layer inside the through hole. The forming of the through hole includes forming, on a surface of the conductor layer on the insulating layer side, a recess having a conical shape that tapers toward the opposite side with respect to the through hole, with a center of the recess offset from a center of the first opening in a plan view.

According to an embodiment of the present invention, it may be possible that peeling between the via conductor and the conductor layer is suppressed and connection reliability in the wiring substrate is improved. Further, it may be possible that such a wiring substrate with good connection reliability can be more easily manufactured compared to the conventional art.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a conductor layer;
an insulating layer formed on the conductor layer such that the insulating layer is covering the conductor layer; and
a via conductor formed in a through hole penetrating through the insulating layer such that the through hole has a first opening on an opposite side with respect to the conductor layer and a second opening facing the conductor layer and that the via conductor is connecting to the conductor layer,
wherein the conductor layer has a surface facing the via conductor and having a recess communicating with the through hole such that the recess is smaller than the second opening and has a conical shape tapering toward an opposite side with respect to the via conductor and the recess has a center on the surface of the conductor layer that is offset from a center of the first opening of the through hole.

2. The wiring substrate according to claim 1, wherein the conductor layer is formed such that a tip of the recess facing away from the through hole is offset from the center of the first opening of the through hole and that the offset of the tip from the center of the first opening is greater than the offset of the center of the recess on the surface from the center of the first opening of the through hole.

3. The wiring substrate according to claim 1, wherein the insulating layer is formed such that a center of the second opening of the through hole is offset in a first direction relative to the center of the first opening of the through hole, and the conductor layer is formed such that the tip of the recess facing away from the through hole is offset in the first direction relative to the center of the recess on the surface.

4. The wiring substrate according to claim 1, wherein the insulating layer and the conductor layer are formed such that when a first angle is greater than a second angle, a third angle is greater than a fourth angle, and when the second angle is greater than the first angle, the fourth angle is greater than the third angle, where in a cross section along a thickness direction of the wiring substrate taken along a cutting line passing through a center of the through hole, the insulating layer has a first wall surface and a second wall surface facing each other across the through hole, the first wall surface has the first angle relative to the thickness direction, the second wall surface has the second angle relative to the thickness direction, the conductor layer has two wall surfaces facing each other across the recess in the cross section, a third wall on the first wall surface side has the third angle relative to the thickness direction, a fourth wall surface on the second wall surface side has the fourth angle relative to the thickness direction.

5. The wiring substrate according to claim 2, wherein the insulating layer is formed such that a center of the second opening of the through hole is offset in a first direction relative to the center of the first opening of the through hole, and the conductor layer is formed such that the tip of the recess facing away from the through hole is offset in the first direction relative to the center of the recess on the surface.

6. The wiring substrate according to claim 2, wherein the insulating layer and the conductor layer are formed such that when a first angle is greater than a second angle, a third angle is greater than a fourth angle, and when the second angle is greater than the first angle, the fourth angle is greater than the third angle, where in a cross section along a thickness direction of the wiring substrate taken along a cutting line passing through a center of the through hole, the insulating layer has a first wall surface and a second wall surface facing each other across the through hole, the first wall surface has the first angle relative to the thickness direction, the second wall surface has the second angle relative to the thickness direction, the conductor layer has two wall surfaces facing each other across the recess in the cross section, a third wall on the first wall surface side has the third angle relative to the thickness direction, a fourth wall surface on the second wall surface side has the fourth angle relative to the thickness direction.

7. The wiring substrate according to claim 3, wherein the insulating layer and the conductor layer are formed such that when a first angle is greater than a second angle, a third angle is greater than a fourth angle, and when the second angle is greater than the first angle, the fourth angle is greater than the third angle, where in a cross section along a thickness direction of the wiring substrate taken along a cutting line passing through a center of the through hole, the insulating layer has a first wall surface and a second wall surface facing each other across the through hole, the first wall surface has the first angle relative to the thickness direction, the second wall surface has the second angle relative to the thickness direction, the conductor layer has two wall surfaces facing each other across the recess in the cross section, a third wall on the first wall surface side has the third angle relative to the thickness direction, a fourth wall surface on the second wall surface side has the fourth angle relative to the thickness direction.

8. The wiring substrate according to claim 1, wherein the insulating layer is formed such that a center of the second opening of the through hole is offset in a first direction relative to the center of the first opening of the through hole.

9. The wiring substrate according to claim 1, wherein the conductor layer is formed such that the tip of the recess facing away from the through hole is offset in a first direction relative to the center of the recess on the surface.

10. The wiring substrate according to claim 1, wherein the insulating layer and the conductor layer are formed such that a first angle is greater than a second angle and that a third angle is greater than a fourth angle, where in a cross section along a thickness direction of the wiring substrate taken along a cutting line passing through a center of the through hole, the insulating layer has a first wall surface and a second wall surface facing each other across the through hole, the first wall surface has the first angle relative to the thickness direction, the second wall surface has the second angle relative to the thickness direction, the conductor layer has two wall surfaces facing each other across the recess in the cross section, a third wall on the first wall surface side has the third angle relative to the thickness direction, a fourth wall surface on the second wall surface side has the fourth angle relative to the thickness direction.

11. The wiring substrate according to claim 1, wherein the insulating layer and the conductor layer are formed such that the second angle is greater than the first angle and that the fourth angle is greater than the third angle, where in a cross section along a thickness direction of the wiring substrate taken along a cutting line passing through a center of the through hole, the insulating layer has a first wall surface and a second wall surface facing each other across the through hole, the first wall surface has the first angle relative to the thickness direction, the second wall surface has the second angle relative to the thickness direction, the conductor layer has two wall surfaces facing each other across the recess in the cross section, a third wall on the first wall surface side has the third angle relative to the thickness direction, a fourth wall surface on the second wall surface side has the fourth angle relative to the thickness direction.

12. A method for manufacturing a wiring substrate, comprising:
forming a conductor layer;
forming an insulating layer on a conductor layer such that the insulating layer covers the conductor layer;
forming a through hole in the insulating layer such that the through hole has a first opening facing away from the conductor layer and a second opening facing the conductor layer; and
forming a via conductor in the through hole of the insulating layer such that the via conductor is connected to the conductor layer in the through hole,
wherein the forming of the through hole includes forming, on a surface of the conductor layer on an insulating layer side, a recess having a conical shape that tapers toward an opposite side with respect to the through hole such that a center of the recess is offset from a center of the first opening of the through hole.

13. The method for manufacturing a wiring substrate according to claim 12, wherein the forming of the insulating layer includes forming a resin layer having a protective film on a surface on an opposite side with respect to the conductor layer, and the forming of the through hole includes irradiating a laser beam toward the protective film.

14. The method for manufacturing a wiring substrate according to claim 12, wherein the forming of the through hole includes irradiating a laser beam in an ultraviolet band.

15. The method for manufacturing a wiring substrate according to claim 13, wherein the forming of the through hole includes irradiating a laser beam in an ultraviolet band.

16. The method for manufacturing a wiring substrate according to claim 13, wherein the protective film includes polyethylene naphthalate.

17. The method for manufacturing a wiring substrate according to claim 13, wherein the irradiating of the laser beam includes enhancing power at a central part of a spot of the laser beam more than at a peripheral part of the spot by using the protective film.

18. The method for manufacturing a wiring substrate according to claim 15, wherein the protective film includes polyethylene naphthalate.

19. The method for manufacturing a wiring substrate according to claim 15, wherein the irradiating of the laser beam includes enhancing power at a central part of a spot of the laser beam more than at a peripheral part of the spot by using the protective film.

20. The method for manufacturing a wiring substrate according to claim 18, wherein the irradiating of the laser beam includes enhancing power at a central part of a spot of the laser beam more than at a peripheral part of the spot by using the protective film.
